(19) United States
(12) Patent Application Publication
(10) Pub. No.: US 2007/0024332 A1
(43) Pub. Date: Feb. 1, 2007

(54) All MOS power-on-reset circuit

(75) Inventor: Scott C. McLeod, Oro Valley, AZ (US)

Correspondence Address: MEYERTONS, HOOD, KIVLIN, KOWERT & GOETZEL, P.C., 700 LAVACA, SUITE 800, AUSTIN, TX, 78701, US

(73) Assignee: Standard Microsystems Corporation

(21) Appl. No.: 11/192,152

(22) Filed: Jul. 28, 2005

(51) Int. Cl. H03L 7/00

(52) U.S. Cl. 327/143

(57) ABSTRACT

A reliable, integrated POR (power-on-reset) circuit with a compact and small area. In one set of embodiments, the POR circuit comprises NMOS and PMOS devices, where a combination of the respective threshold voltages of the NMOS and PMOS devices is used to set the POR threshold. The NMOS and PMOS devices may be coupled in a configuration resulting in a POR threshold that is a function of the PMOS threshold voltage and a scaled version of the NMOS threshold voltage. The scaling factor may be a function of the transconductance parameters of the NMOS and PMOS devices. Additional NMOS devices may be configured in the POR circuit to provide hysteresis functionality, with one of the NMOS devices coupling to one of the original NMOS devices. The scaling factor used in determining the POR threshold in case of a falling supply voltage may then be a function of the transconductance parameters of the original NMOS and PMOS devices and the additional NMOS device coupling to one of the original NMOS devices.

### BACKGROUND OF THE INVENTION

1. Field of the Invention

This invention relates generally to the field of integrated circuit design and, more particularly, to the design of power-on-reset (POR) circuits.

2. Description of the Related Art

A POR (power-on-reset) signal is typically required by digital circuits such as memory elements, flip-flops, microcontrollers and central processing units to set an initial state immediately after powering on the circuit. For example, when powered on, most of the programmed or programmable type logic circuits, in particular microprocessors, must be set in a zero state or RESET state in order to insure that no undetermined logic states are present in any portion of the circuit. This signal has been traditionally generated externally, typically using an external RC circuit or simply a switch, the latter having to be manually operated in most cases.

More recently, integrated POR circuits have been incorporated into system on a chip (SOCs) circuits and/or more extensive controller chips and integrated circuits. Some integrated POR circuits typically deliver a RESET signal when the supply voltage rises and reaches a first switching threshold voltage, and release the RESET signal upon the supply voltage reaching a second switching threshold voltage. One problem of integrating a POR circuit according to this technique is with the rate of rise of the power supply, which is generally quite slow. As a result, the RC time constant needs to be very large for successful generation of a POR signal. Realization of such high time constants on chip may take up too much space to be practical, although the same time constant may be easily realized in an external circuit.

Consequently, many integrated POR circuits feature metal oxide semiconductor (MOS) devices, which can be very small in size, coupling to some very large resistors that may consume excessively large semiconductor die areas. However, there are cases when a reliable POR circuit is required in as compact and small an area as possible, without compromising any of the required functionality of such a POR circuit.

Other corresponding issues related to the prior art will become apparent to one skilled in the art after comparing such prior art with the present invention as/described herein.

### SUMMARY OF THE INVENTION

In one set of embodiments, a reliable power-on-reset (POR) function is realized in a compact integrated POR circuit, minimizing the required area without compromising functionality. In one embodiment, a POR circuit having a POR output comprises a first pair of MOS devices coupling to a second pair of MOS devices. The POR circuit may be configured to couple to a voltage supply, which is configured to provide a supply voltage powering the POR circuit. In a default state, the POR output may be configured to provide a reset signal disabling select circuit components to which it may be coupled. The POR circuit may be operable to monitor a rise of the supply voltage, and to change the voltage state of the POR output from a reset state to a non-reset state upon the supply voltage reaching a first POR threshold voltage value defined by a function of the PMOS threshold voltage and a scaled version of the NMOS threshold voltage. In one embodiment, in determining the first POR threshold voltage value, the scaling factor for the NMOS threshold voltage is a function of the respective transconductance parameters of the first and second pairs of NMOS devices comprised in the POR circuit.

In one embodiment, the POR circuit may further comprise a first additional NMOS device coupled to the first pair of MOS devices to provide hysteresis functionality for the POR circuit. The first additional NMOS device may also couple to a second additional NMOS device, which may operate to control the hysteresis functionality. Thus, after having changed the voltage state of the POR output from a reset state to a non-reset state, the POR circuit may be operable to monitor a fall of the supply voltage, and to change the voltage state of the POR output from a non-reset state back to a reset state upon the supply voltage reaching a second POR threshold voltage value also defined by a function of the PMOS threshold voltage and a scaled version of the NMOS threshold voltage. In one embodiment, in determining the second POR threshold voltage value, the scaling factor for the NMOS threshold voltage is a function of the respective transconductance parameters of the first and second pairs of NMOS devices and the transconductance of the first additional NMOS device comprised in the POR circuit.

In one set of embodiments, the first pair of MOS devices and second pair of MOS devices may each comprise a respective PMOS device and a respective NMOS device, which may be coupled in series via their respective drain terminals. The respective source terminals of the PMOS devices may be coupling to voltage supply Vdd, and the respective source terminals of the NMOS devices may be coupling to signal ground Vss. Each transistor device's transconductance parameter may be adjusted according to the device's channel width to channel length ratio.

Thus, various embodiments of the invention may provide a means for designing and building a reliable integrated POR circuit with a compact and small area. In one set of embodiments, the POR circuit comprises NMOS and PMOS devices, where a combination of the respective threshold voltages of the NMOS and PMOS devices is used to set the power-on-reset threshold.

### BRIEF DESCRIPTION OF THE DRAWINGS

The foregoing, as well as other objects, features, and advantages of this invention may be more completely understood by reference to the following detailed description when read together with the accompanying drawings in which:

FIG. 1 illustrates one embodiment of a power-on-reset (POR) circuit; and

FIG. 2 illustrates an alternate embodiment of a POR circuit that includes hysteresis circuitry.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents, and alternatives falling within the spirit and scope of the present invention as defined by the appended claims. Note, the headings are for organizational purposes only and are not meant to be used to limit or interpret the description or claims. Furthermore, note that the word “may” is used throughout this application in a permissive sense (i.e., having the potential to, being able to), not a mandatory sense (i.e., must).” The term “include”, and derivations thereof, mean “including, but not limited to”. The term “coupled” means “directly or indirectly connected”.

### DETAILED DESCRIPTION OF THE PREFERRED EMBODIMENTS

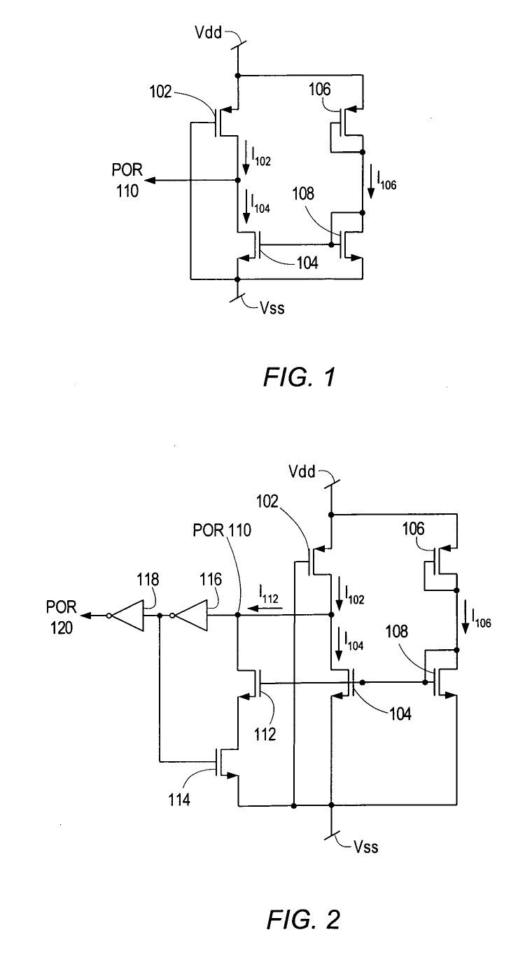

As used herein, the numeric subscript of a particular variable and/or parameter in equations (1) through (29) identifies the identically numbered respective MOS device in FIG. 1 and/or FIG. 2, to which the particular variable and/or parameter corresponds.

FIG. 1 shows one embodiment of an accurate, low variation and compact size POR (power-on-reset) circuit that may be coupled to a voltage supply configured to provide supply voltage Vdd. The POR circuit may be constructed using NMOS (n-channel metal-oxide semiconductor) devices 104 and 108, and PMOS (p-channel MOS) devices 102 and 106. PMOS device 106 may be coupled in series to NMOS device 108, with the respective drain terminals of PMOS 106 and NMOS 108 coupled together. In one embodiment, a POR output 110 is generated from the drain terminal of PMOS 102 which is coupled to the drain terminal of NMOS 104, as shown. By coupling the drain terminal of PMOS 106 to its gate terminal, and the drain terminal of NMOS 108 to its gate terminal, as shown in FIG. 1, supply voltage Vdd may be divided between PMOS 106 and NMOS 108 as the sum of the respective gate-source voltages of PMOS device 106 and NMOS device 108:
VGS₁₀₆+VGS₁₀₈=VddVGS₁₀₆=Vdd−VGS₁₀₈. (1)

The current I₁₀₆ flowing through PMOS device 106 and NMOS device 108 may be expressed as:

$$\begin{matrix}{I}_{106} = \frac{{K}_{P}}{2} * \frac{{W}_{106}}{{L}_{106}} * {( {VGS}_{106} - {V}_{TP} )}^{2} \\ = \frac{{K}_{N}}{2} * \frac{{W}_{108}}{{L}_{108}} * {( {VGS}_{108} - {V}_{TN} )}^{2}\end{matrix} \qquad ( 2 )$$

where Kₚ and Kₙ represent the transconductance of PMOS and NMOS devices, respectively, for any given (specified) fabrication process, and W/L represents the channel width to channel length ratio of a given transistor device. V_{TP} and V_{TN} represent the threshold voltage of PMOS and NMOS devices, respectively. A transconductance parameter β may be considered for each respective MOS device, based on the respective MOS device's transconductance and channel width to channel length ratio taken from equation (2), expressed as:

$$\begin{matrix}{β}_{106} = {K}_{P} * \frac{{W}_{106}}{{L}_{106}} \\ and & ( 3 ) \\ {β}_{108} = {K}_{N} * \frac{{W}_{108}}{{L}_{108}} . & ( 4 )\end{matrix}$$

While not specifically shown here, β values for NMOS 104 and PMOS 102 may be similarly expressed. Equation (2) may then be re-written by substituting the appropriate β values:

$${I}_{106} = \frac{{β}_{106}}{2} * {( {VGS}_{106} - {V}_{TP} )}^{2} = \frac{{β}_{108}}{2} * {( {VGS}_{108} - {V}_{TN} )}^{2} \qquad ( 5 )$$

Starting from the resulting equality
β₁₀₆*(Vdd−VGS₁₀₈−V_{TP})²=β₁₀₈*(VGS₁₀₈−V_{TN})², (6)
through the following series of operations:

$$\begin{matrix}\sqrt{{β}_{106}} * ( Vdd - {VGS}_{108} - {V}_{TP} ) = \sqrt{{β}_{108}} * ( {VGS}_{108} - {V}_{TN} ) & ( 7 ) \\ ( Vdd - {VGS}_{108} - {V}_{TP} ) = \sqrt{\frac{{β}_{108}}{{β}_{106}}} * ( {VGS}_{108} - {V}_{TN} ) , & ( 8 ) \\ Vdd - {VGS}_{108} - {V}_{TP} = \sqrt{\frac{{β}_{108}}{{β}_{106}}} * {VGS}_{108} - \sqrt{\frac{{β}_{108}}{{β}_{106}}} * {V}_{TN} , \\ and & ( 9 ) \\ Vdd - {V}_{TP} + \sqrt{\frac{{β}_{108}}{{β}_{106}}} * {V}_{TN} = {VGS}_{108} * ( 1 + \sqrt{\frac{{β}_{108}}{{β}_{106}}} ) , & ( 10 )\end{matrix}$$

an expression for VGS₁₀₈ may be derived:

$${VGS}_{108} = \frac{Vdd - {V}_{TP} + \sqrt{\frac{{β}_{108}}{{β}_{106}}} * {V}_{TN}}{1 + \sqrt{\frac{{β}_{108}}{{β}_{106}}}} . \qquad ( 11 )$$

Similarly, the current flowing through NMOS 104 may be expressed as:

$${I}_{104} = \frac{{K}_{N}}{2} * \frac{{W}_{104}}{{L}_{104}} * {( {VGS}_{104} - {V}_{TN} )}^{2} = \frac{{β}_{104}}{2} * {( {VGS}_{108} - {V}_{TN} )}^{2} , \qquad ( 12 )$$

from which

$$\begin{matrix}{I}_{104} = \frac{{β}_{104}}{2} * {( \frac{Vdd - {V}_{TP} + \sqrt{\frac{{β}_{108}}{{β}_{106}}} * {V}_{TN}}{1 + \sqrt{\frac{{β}_{108}}{{β}_{106}}}} - \frac{( 1 + \sqrt{\frac{{β}_{108}}{{β}_{106}}} ) * {V}_{TN}}{1 + \sqrt{\frac{{β}_{108}}{{β}_{106}}}} )}^{2} , \\ and & ( 13 ) \\ {I}_{104} = \frac{{β}_{104}}{2} * {( \frac{Vdd - {V}_{TP} - {V}_{TN}}{1 + \sqrt{\frac{{β}_{108}}{{β}_{106}}}} )}^{2} . & ( 14 )\end{matrix}$$

The current flowing through PMOS 102 may also be written:

$${I}_{102} = \frac{{K}_{P}}{2} * \frac{{W}_{102}}{{L}_{102}} * {( {VGS}_{102} - {V}_{TP} )}^{2} = \frac{{β}_{102}}{2} * {( Vdd - {V}_{TP} )}^{2} . \qquad ( 15 )$$

When first applying a supply voltage Vdd to the POR circuit, POR output 110 may initially be asserted, and may change states when I₁₀₂ and I₁₀₄ are of equal value. Thus, combining equations (14) and (15):

$${β}_{106} * ( \frac{Vdd - {V}_{TP} - {V}_{TN}}{1 + \sqrt{\frac{{β}_{108}}{{β}_{106}}}} ) = {β}_{102} * {( Vdd - {V}_{TP} )}^{2} , \qquad ( 16 )$$

from which

$$\sqrt{{β}_{104}} * {( \frac{Vdd - {V}_{TP} - {V}_{TN}}{1 + \sqrt{\frac{{β}_{108}}{{β}_{106}}}} )}^{2} = \sqrt{{β}_{ 102}} * ( Vdd - {V}_{TP} ) , \qquad ( 17 )$$

thus obtaining the following relationship between Vdd and V_{TN} and V_{TP}.

$$\sqrt{\frac{{β}_{104}}{{β}_{102}}} * \frac{1}{1 + \sqrt{\frac{{β}_{108}}{{β}_{106}}}} * ( Vdd - {V}_{TP} - {V}_{TN} ) = Vdd - {V}_{TP} . \qquad ( 18 )$$

Defining a scaling factor η as a function of the various n parameters:

$$η = \sqrt{\frac{{β}_{104}}{{β}_{102}}} * \frac{1}{1 + \sqrt{\frac{{β}_{108}}{{β}_{106}}}} = \sqrt{\frac{{β}_{104}}{{β}_{102}}} * \frac{\sqrt{{β}_{106}}}{\sqrt{{β}_{106}} + \sqrt{{β}_{108}}} , \qquad ( 19 )$$

the value of Vdd at which POR output 110 changes state from a reset mode to a non-reset mode may be expressed by the following equation:

$$Vdd = {V}_{TP} + \frac{η}{η - 1} * {V}_{TN} . \qquad ( 20 )$$

Thus, a threshold for POR output 110 may be set by adjusting the respective W/L ratios of NMOS devices 104 and 108, and PMOS devices 102 and 106, taking into consideration the device transconductance parameters (Kₚ and Kₙ), and V_{TP} and V_{TN} corresponding to the fabrication process used in manufacturing the POR circuit.

FIG. 2 shows another embodiment of a POR circuit. In this embodiment, additional NMOS devices 112 and 114, and inverters 116 and 118 have been coupled to the POR circuit of FIG. 1 in order to add hysteresis functionality. In this embodiment, as Vdd begins to ramp up when the voltage supply is turned on, NMOS 114 remains turned off until the POR threshold (from equation (20)) is reached. Once the POR threshold has been crossed, NMOS 114 turns on. Subsequently, for Vdd decreasing, a second POR threshold may occur at a value of Vdd when (I₁₀₄+I₁₁₂) and I₁₀₂ are equal.

I₁₁₂ may then be written as:

$${I}_{112} = \frac{{K}_{N}}{2} * \frac{{W}_{112}}{{L}_{112}} * {( {VGS}_{112} - {V}_{TN} )}^{2} = \frac{{β}_{112}}{2} * {( {VGS}_{108} - {V}_{TN} )}^{2} \qquad ( 21 )$$

Substituting for VGS₁₀₈ from equation (11), I₁₁₂ may be re-written as:

$${I}_{112} = \frac{{β}_{112}}{2} * {( \frac{Vdd - {V}_{TP} + \sqrt{\frac{{β}_{108}}{{β}_{106}}} * {V}_{TN}}{1 + \sqrt{\frac{{β}_{108}}{{β}_{106}}}} - \frac{( 1 + \sqrt{\frac{{β}_{108}}{{β}_{106}}} ) * {V}_{TN}}{1 + \sqrt{\frac{{β}_{108}}{{β}_{106}}}} )}^{2} . \qquad ( 22 )$$

Simplifying equation (22), I₁₁₂ may be expressed as:

$${I}_{112} = \frac{{β}_{112}}{2} * {( \frac{Vdd - {V}_{TP} - {V}_{TN}}{1 + \sqrt{\frac{{β}_{108}}{{β}_{106}}}} )}^{2} \qquad ( 23 )$$

Using the results of equations (14) and (23), respectively, the sum of I₁₀₄ and I₁₁₂ may be expressed as:

$${I}_{104} + {I}_{112} = \frac{( {β}_{104} + {β}_{112} )}{2} * {( \frac{Vdd - {V}_{TP} - {V}_{TN}}{1 + \sqrt{\frac{{β}_{108}}{{β}_{106}}}} )}^{2} \qquad ( 24 )$$

Equating the sum of I₁₀₄ and I₁₁₂ with I₁₀₂:

$$( {β}_{104} + {β}_{112} ) * {( \frac{Vdd - {V}_{TP} - {V}_{TN}}{1 + \sqrt{\frac{{β}_{108}}{{β}_{106}}}} )}^{2} = {β}_{102} * {( Vdd - {V}_{TP} )}^{2} , \qquad ( 25 )$$

from which:

$$\sqrt{{β}_{ 104} + {β}_{ 112}} * {( \frac{Vdd - {V}_{TP} - {V}_{TN}}{1 + \sqrt{\frac{{β}_{108}}{{β}_{106}}}} )}^{2} = \sqrt{{β}_{ 102}} * ( Vdd - {V}_{TP} ) , \qquad ( 26 )$$

leading to:

$$\sqrt{\frac{{β}_{104} + {β}_{112}}{{β}_{102}}} * \frac{1}{1 + \sqrt{\frac{{β}_{108}}{{β}_{106}}}} * ( Vdd - {V}_{TP} - {V}_{TN} ) = Vdd - {V}_{TP} . \qquad ( 27 )$$

Defining a scaling factor η′ as a function of the various β parameters:

$${η}^{′} = \sqrt{\frac{{β}_{104} + {β}_{112}}{{β}_{102}}} * \frac{1}{1 + \sqrt{\frac{{β}_{108}}{{β}_{106}}}} = \sqrt{\frac{{β}_{104} + {β}_{112}}{{β}_{102}}} * \frac{\sqrt{{β}_{106}}}{\sqrt{{β}_{106}} + \sqrt{{β}_{108}}} \qquad ( 28 )$$

the value of Vdd at which POR output 120 changes state from a non-reset mode to a reset mode may be expressed by the following equation:

$$Vdd = {V}_{TP} + \frac{{η}^{′}}{{η}^{′} - 1} * {V}_{TN} . \qquad ( 29 )$$

In a manner similar to setting the threshold of POR output 110 (and POR output 120) while monitoring an increase in the value of Vdd, a threshold of POR output 120 while monitoring a decrease in the value of Vdd may be set by adjusting the respective W/L ratios of NMOS devices 104, 108, and 112, and PMOS devices 102 and 106, taking into consideration the device transconductance parameters (Kₚ and Kₙ), and V_{TP} and V_{TN} corresponding to the fabrication process used in manufacturing the POR circuit.

In the circuit configuration shown in FIG. 2, inverter 116 may operate to provide a proper assertion level for turning NMOS device 114 on and off, with inverter 118 restoring the assertion level of POR output 110 to POR output 120.

Thus, various embodiments of the invention may provide a means for designing and building a reliable, compact integrated POR circuit. In one set of embodiments, the POR function may be accomplished with only MOS devices, and the power-on-reset threshold may be a function of the PMOS threshold voltage and a scaled version of the NMOS threshold voltage.

Although the embodiments above have been described in considerable detail, other versions are possible. Numerous variations and modifications will become apparent to those skilled in the art once the above disclosure is fully appreciated. It is intended that the following claims be interpreted to embrace all such variations and modifications. Note the section headings used herein are for organizational purposes only and are not meant to limit the description provided herein or the claims attached hereto.

We claim:

1. A power-on-reset (POR) circuit having a POR output, the POR circuit comprising:
first and second pairs of transistors, wherein the POR circuit is configured to be coupled to a voltage supply, wherein the voltage supply is configured to provide a supply voltage, wherein the POR circuit is operable to monitor a rise of the supply voltage, and to change a voltage state of the POR output from a POR state to a non-POR state upon the supply voltage reaching a first threshold value;
wherein the first threshold value is defined by a function of:
a first device-characteristic of respective first transistors of the first and second pairs of transistors; and
a function of a first scaling factor and the first device-characteristic of respective second transistors of the first and second pairs of transistors, wherein the first scaling factor is a function of a respective second device-characteristic of each transistor of the first and second pairs of transistors.

2. The POR circuit of claim 1, further comprising a fifth transistor coupled to the first pair of transistors, and a sixth transistor coupled to the fifth transistor, wherein the POR circuit is further operable to monitor a fall of the supply voltage, and to change the voltage state of the POR output from a non-POR state to a POR state upon the supply voltage reaching a second threshold value;
wherein the second threshold value is defined by a function of:
the first device-characteristic of the respective first transistors of the first and second pairs of transistors; and
a function of a second scaling factor and the first device-characteristic of the fifth and sixth transistors and the respective second transistors of the first and second pairs of transistors, wherein the second scaling factor is a function of the respective second device-characteristic of each transistor of the first and second pairs of transistors, and the respective second device-characteristic of the fifth transistor.

3. The POR circuit of claim 2, wherein the respective first transistors of the first and second pairs of transistors comprise PMOS devices, and the respective second transistors of the first and second pairs of transistors and the fifth and sixth transistors comprise NMOS devices.

4. The POR circuit of claim 3, wherein the first device-characteristic comprises a switching threshold voltage.

5. The POR circuit of claim 4, wherein the second device-characteristic comprises a transconductance parameter that is a function of transistor geometry and process parameters.

6. The POR circuit of claim 5, wherein the transistor geometry comprises transistor channel-width to transistor channel-length ratio.

7. The POR circuit of claim 2, wherein the POR state comprises a high voltage and the non-POR state comprises a low voltage.

8. A method for generating a POR output signal, the method comprising:
a POR circuit monitoring a rise of a supply voltage; and
the POR circuit changing a voltage state of the POR output signal from a POR state to a non-POR state upon the supply voltage reaching a first threshold value;
wherein the first threshold value is defined by a function of:
a first device-characteristic of respective first transistors of first and second pairs of transistors comprised in the POR circuit; and
a function of a first scaling factor and the first device-characteristic of respective second transistors of the first and second pairs of transistors, wherein the first scaling factor is a function of a respective second device-characteristic of each transistor of the first and second pairs of transistors.

9. The method of claim 8, further comprising:
the POR circuit monitoring a fall of the supply voltage; and
the POR circuit changing a voltage state of the POR output signal from a non-POR state to a POR state upon the supply voltage reaching a second threshold value;
wherein the second threshold value is defined by a function of:
the first device-characteristic of the respective first transistors of the first and second pairs of transistors; and
a function of a second scaling factor and the first device-characteristic of a fifth transistor coupled to the first pair of transistors and a sixth transistor coupled to the fifth transistor and the respective second transistors of the first and second pairs of transistors, wherein the second scaling factor is a function of the respective second device-characteristic of each transistor of the first and second pairs of transistors, and the respective second device-characteristic of the fifth transistor.

10. The method of claim 9, wherein the respective first transistors of the first and second pairs of transistors comprise PMOS devices, and the respective second transistors of the first and second pairs of transistors and the fifth and sixth transistors comprise NMOS devices.

11. The method of claim 10, wherein the first device-characteristic comprises a switching threshold voltage.

12. The method of claim 11, wherein the second device-characteristic comprises a transconductance parameter that is a function of transistor geometry and process parameters.

13. The POR circuit of claim 12, wherein the transistor geometry comprises transistor channel-width to transistor channel-length ratio.

14. The method of claim 9, wherein the POR state comprises a high voltage and the non-POR state comprises a low voltage.

15. A POR circuit comprising:
a first PMOS device, wherein a drain terminal of the first PMOS device is configured to couple to a gate terminal of the first PMOS device, and wherein a source terminal of the first PMOS device is configured to couple to a voltage supply (Vdd);
a first NMOS device, wherein a drain terminal of the first NMOS device is configured to couple to a drain terminal of the first PMOS device, wherein the drain terminal of the first NMOS device is configured to couple to a gate terminal of the first NMOS device, and wherein and a source terminal of the first NMOS device is configured to couple to signal ground (Vss);
a second PMOS device, wherein a gate terminal of the second PMOS device is configured to couple to Vss, and wherein a source terminal of the second PMOS device is configured to couple to Vdd; and
a second NMOS device, wherein a drain terminal of the second NMOS device is configured to couple to a drain terminal of the second PMOS device, wherein a gate terminal of the second NMOS device is configured to couple to the gate terminal of the first NMOS device, and wherein a source terminal of the second NMOS device is configured to couple to Vss;
wherein the coupled respective drain terminals of the second PMOS device and the second NMOS device comprise a first output of the POR circuit.

16. The POR circuit of claim 15, further comprising:
a third NMOS device, wherein a drain terminal of third NMOS device is configured to couple to the first output, and wherein a gate terminal of the third NMOS device is configured to couple to the gate terminal of the second NMOS device;
a fourth NMOS device, wherein a drain terminal of the fourth NMOS device is configured to couple to a source terminal of the third NMOS device, and wherein a source terminal of the fourth NMOS device is configured to couple to Vss;
a first inverter, wherein an input of the first inverter is configured to couple to the first output, and wherein an output of the first inverter is configured to couple to a gate terminal of the fourth NMOS device; and
a second inverter, wherein an input of the second inverter is configured to couple to the output of the first inverter, and wherein an output of the second inverter is configured as a second output of the POR circuit.
